(19) United States
(12) Patent Application Publication
(10) Pub. No.: US 2025/0024747 A1
(43) Pub. Date: Jan. 16, 2025

(54) THIN FILM PROCESSING METHOD, LIGHT-EMITTING DIODE PREPARATION METHOD, AND LIGHT-EMITTING DIODE

(71) Applicant: TCL TECHNOLOGY GROUP CORPORATION, Huizhou, Guangdong (CN)

(72) Inventors: Xindi MO, Huizhou, Guangdong (CN); Jianxin ZHANG, Huizhou, Guangdong (CN); Yiran YAN, Huizhou, Guangdong (CN); Zitong AO, Huizhou, Guangdong (CN); Fan YANG, Huizhou, Guangdong (CN); Song MA, Huizhou, Guangdong (CN)

(73) Assignee: TCL TECHNOLOGY GROUP CORPORATION, Huizhou, Guangdong (CN)

(21) Appl. No.: 18/713,658

(22) PCT Filed: Nov. 24, 2022
(86) PCT No.: PCT/CN2022/133958

§ 371 Date: May 26, 2024

(30) Foreign Application Priority Data
Nov. 26, 2021 (CN) 202111420181.X

(51) Int. Cl. H10K 71/40; H10K 50/16; H10K 102/10

(52) U.S. Cl. CPC H10K 71/40; H10K 50/16; H10K 2102/103

(57) ABSTRACT

A thin film processing method includes: providing an electron transport film layer using a metal oxide as an electron transport material; and annealing the electron transport film layer by means of pulsed light in a protective gas environment having an oxygen content of 25-40 ppm.

### CROSS-REFERENCE TO RELATED APPLICATIONS

This application claims priority to Chinese Patent Application No. 202111420181.X, filed in the China National Intellectual Property Administration on Nov. 26, 2021, and entitled “THIN FILM PROCESSING METHOD”, which is incorporated herein by reference in its entirety.

### TECHNICAL FIELD

The present disclosure relates to a field of display technologies, and in particular, to a thin film processing method, a light-emitting diode preparation method, and a light-emitting diode.

### BACKGROUND

An electron transport layer is an important component in conventional perovskite solar cells and light-emitting diodes. According to the different materials used, the electron transport layer may be divided into an organic electron transport layer and an inorganic electron transport layer. Wherein, the inorganic electron transport layer has the advantages of better thermal stability and less influence by water and oxygen than the organic electron transport layer, and has become a hot research topic in recent years. In particular, the inorganic electron transport layer based on metal oxides have attracted extensive attention in recent years because of their high mobility and suitable energy level positions. With the development of light-emitting diodes, especially the development of Quantum dot light-emitting diode (QLED), metal oxides have become the most widely used materials for electron transport layers in light-emitting diodes.

A light-emitting diode typically includes a hole transport layer, a light-emitting layer, and an electron transport layer.

### Technical Problems

Ambient gases, such as moisture (H₂O) and oxygen (O₂), tend to affect the electron transport layer based on metal oxides, and adversely affect electrical properties of the electron transport layer.

### SUMMARY

Therefore, the present disclosure provides a thin film processing method, a light-emitting diode preparation method, and a light-emitting diode.

An embodiment of the present disclosure provides a method of processing a thin film, the method includes:
providing an electron transport layer using a metal oxide as an electron transport material; and
performing an annealing treatment to the electron transport layer by means of pulsed light in a protective gas environment having an oxygen content of 25-40 ppm;
wherein, a frequency of the pulsed light ranges from 1.5 Hz to 4 Hz, and an energy of the pulsed light ranges from 1.20 J/cm² to 2.0 J/cm².

Alternatively, in some embodiments of the present disclosure, a time of the annealing treatment ranges from 2 min to 5 min.

Alternatively, in some embodiments of the present disclosure, a wavelength of the pulsed light adopted in the annealing treatment ranges from 400 nm to 1200 nm.

Alternatively, in some embodiments of the present disclosure, before performing the annealing treatment to the electron transport layer by means of the pulsed light, the method further includes: performing a passivation treatment by hydroxylation on the electron transport layer.

Alternatively, in some embodiments of the present disclosure, the passivation treatment by hydroxylation includes:
placing the electron transport layer in an environment with a humidity of 1 ppm to 10 ppm for 5 min to 20 min.

Alternatively, in some embodiments of the present disclosure, the humidity is provided by one or more of distilled water, deionized water, highly pure water, and ultrapure water.

Alternatively, in some embodiments of the present disclosure, a gas in the environment includes air or a protective gas.

Alternatively, in some embodiments of the present disclosure, a water vapor concentration in the protective gas environment is less than 0.1 ppm.

Alternatively, in some embodiments of the present disclosure, the metal oxide is selected from one or more of ZnO, TiO₂, SnO₂, Ta₂O₃, ZrO₂, NiO, TiLiO, ZnAlO, ZnSnO, ZnLiO, and InSnO.

Alternatively, in some embodiments of the present disclosure, after providing the electron transport layer using the metal oxide as the electron transport material, and before performing the annealing treatment to the electron transport layer by means of the pulsed light, the method includes: annealing the electron transport layer at 80° C.˜ 120° C. for 20 min˜ 60 min.

Correspondingly, an embodiment of the present disclosure further provides a method for preparing a light-emitting diode, including:
providing a substrate; and
stacking a first electrode, a hole transport layer, a light-emitting layer, an electron transport layer and a second electrode on the substrate;
wherein after the electron transport layer is formed, further including: processing the electron transport layer;
the processing includes:
performing an annealing treatment to the electron transport layer by means of pulsed light in a protective gas environment having an oxygen content of 25-40 ppm.

Alternatively, in some embodiments of the present disclosure, a frequency of the pulsed light ranges from 1.5 Hz to 4 Hz, and an energy of the pulsed light ranges from 1.20 J/cm² to 2.0 J/cm².

Alternatively, in some embodiments of the present disclosure, a wavelength of the pulsed light adopted in the annealing treatment ranges from 400 nm to 1200 nm.

Alternatively, in some embodiments of the present disclosure, a time of the annealing treatment ranges from 2 min to 5 min.

Alternatively, in some embodiments of the present disclosure, a water vapor concentration in the protective gas environment is less than 0.1 ppm.

Alternatively, in some embodiments of the present disclosure, after forming the hole transport layer and before the processing, the method further includes: placing the electron transport layer in an environment with a humidity of 1 ppm to 10 ppm for 5 min to 20 min;
wherein the humidity is provided by one or more of distilled water, deionized water, high purity water, and ultrapure water.

Alternatively, in some embodiments of the present disclosure, the first electrode, the hole transport layer, the light-emitting layer, the electron transport layer, and the second electrode are sequentially stacked; the processing is performed before the second electrode is formed.

Alternatively, in some embodiments of the present disclosure, the first electrode, the electron transport layer, the light-emitting layer, the hole transport layer, and the second electrode are sequentially stacked, and the processing is performed before the light-emitting layer is formed.

Alternatively, in some embodiments of the present disclosure, the substrate is selected from a rigid substrate or a flexible substrate, and a material of the rigid substrate is selected from one or more of glass and metal foil; a material of the flexible substrate is selected from one or more of polyethylene terephthalate, polyethylene terephthalate, polyether ether ketone, polystyrene, polyether sulfone, polycarbonate, polyaryl acid ester, polyarylate, polyimide, polyvinyl chloride, polyethylene, polyvinylpyrrolidone, and textile fiber;
and/or, a material of the first electrode is selected from a cathode material or an anode material, the cathode material is selected from one or more of Al, Ag, Au, Cu, Mo and their alloys, and the anode material is selected from one or more of ITO, FTO, and ZTO;
and/or, a material of the second electrode is selected from the cathode material or the anode material, the cathode material is selected from one or more of Al, Ag, Au, Cu, Mo and their alloys, and the anode material is selected from one or more of ITO, FTO, and ZTO;
and/or, a material of the hole transport layer is selected from one of an organic material having a hole transport capability and an inorganic material having a hole transport function, the organic material having the hole transport capability is selected from one or more of poly (9, 9-dioctylfluorene-CO—N-(4-butylphenyl) diphenylamine), poly(N-vinylcarbazole), poly[N,N′-bis(4-butylphenyl)-N,N′-bisphenylbenzidine], poly[(9,9-dioctylfluorenyl-2,7-diyl)-co-(N,N′-diphenyl)-N,N′di(p-butyl-oxy-phenyl)-1, 4-diaMinobenzene), 4,4′,4″-Tris(carbazol-9-yl)-triphenylamine, 4,4′-Di(9H-carbazol-9-yl)-1,1′-biphenyl, N,N′-bis(3-methylphenyl)-N,N′-diphenyl-benzidine, 15N,N′-Bis(1-naphthalenyl)-N,N′-bisphenyl-(1,1′-biphenyl)-4,4′-diamine, graphene, and C60; and the inorganic material having the hole transport function is selected from one or more of NiOₓ, MoOₓ, WOₓ, CrOₓ, CuO, MoSₓ, MoSeₓ, WSₓ, WSeₓ, and CuS, wherein x is a positive number;
and/or, a material of the hole injection layer is selected from one or more of PEDOT:PSS, CuPc, F4-TCNQ, HATCN, a transition metal oxide, and a transition metal chalcogenide compound, the transition metal oxide is selected from one or more of NiOₓ, MoOₓ, WOₓ, CrOₓ, and CuO, and the metal chalcogenide compound is selected from one or more of MoSₓ, MoSeₓ, WSₓ, WSeₓ, and CuS, wherein x is the positive number;
and/or, a material of the light-emitting layer is selected from one of a direct band gap compound semiconductor having light-emitting ability and a perovskite type semiconductor, the direct band gap compound semiconductor having light-emitting ability includes one or more of a group II-VI compound, a group III-V compound, a group II-V compound, a group III-VI compound, a group IV-VI compound, a group I-III-VI compound, a group II-IV-VI compound or a group IV elemental substance, the group II-VI compound is selected from one or more of CdS, CdSe, CdTe, ZnS, ZnSe, ZnTe, HgS, HgSe, HgTe, PbS, PbSe, PbTe and other binary, ternary, quaternary II-VI semiconductor nanocrystals; the group III-V compound is selected from one or more of GaP, GaAs, InP, InAs, and other binary, ternary, quaternary III-V semiconductor nanocrystals; the group II-V compound is selected from one or more of GaP, GaAs, InP, InAs, and other binary, ternary, quaternary III-V semiconductor nanocrystals; the perovskite type semiconductor is selected from one or more of a doped or non-doped inorganic perovskite type semiconductor, and an organic-inorganic hybrid perovskite type semiconductor, wherein a general structural formula of the inorganic perovskite type semiconductor is AMX₃, and the general structural formula of the organic-inorganic hybrid perovskite type semiconductor is BMX₃, wherein A is Cs⁺, B is an organic amine cation, M is a divalent metal cation, X is a halogen anion, the divalent metal cation includes one of Pb²⁺, Sn²⁺, Cu²⁺, Ni²⁺, Cd²⁺, Cr²⁺, Mn²⁺, Co²⁺, Fe²⁺, Ge²⁺, Yb²⁺, and Eu²⁺; the halogen anion includes one of Cl⁻, Br⁻, and I⁻; the organic amine cation includes one of CH₃(CH₂)ₙ₋₂NH₃⁺ (n≥2) and NH₃(CH₂)ₙNH₃²⁺ (n≥2).

Correspondingly, an embodiment of the present disclosure further provides a light-emitting device prepared by the above-mentioned method.

### Advantageous Effects

An embodiment of the present disclosure provides a thin film processing method that uses pulsed light to anneal the electron transport layer in a protective gas environment with an oxygen content of 25 to 40 ppm. In this way, oxygen in the environment fills the oxygen vacancies of the metal oxide, and oxygenates the oxygen vacancies of the metal oxide, which reduces the oxygen vacancies on the surface of the electron transport layer, thereby reducing the amount of electrons in the electron transport film layer, and thereby improving the problem of charge injection imbalance in a device based on the electron transport layer. In addition, annealing with the pulsed light may also provide thermal energy for oxygen-filled oxygen vacancies in the metal oxide; at the same time, because there will be a certain amount of water in the preparation process of the electron transport layer, a small amount of O₂ will capture the free electrons produced by the chemical interaction between water and the metal oxide, so that O₂ will be converted into O²⁻, and O⁻, thereby reducing the electron concentration of the metal oxide and reducing the conductivity; in addition, annealing with the pulsed light may also remove excess moisture in the electron transport layer, and improve the adverse effect of residual moisture on device performance; the annealing method anneals quickly, shortens the time required for annealing, and may also greatly reduce thermal damage to the device during the annealing process, so that the electron transport layer obtained by this post-processing method has excellent electron transport performance.

### BRIEF DESCRIPTION OF THE DRAWINGS

In order to illustrate the technical solutions of the present disclosure clearly, the following will briefly describe the accompanying drawings involved in the description of embodiments. It will be apparent that the drawings in the following description are merely some of embodiments of the present disclosure, and other drawings may be obtained by those skilled in the art without involving any inventive effort based on these drawings.

FIG. 1 is a schematic diagram of oxygen vacancies in the zinc oxide structure when pulsed light is used to treat the electron transport layer provided in Example 1 of the present disclosure.

FIG. 2 is a schematic structural diagram of zinc oxide after the oxygen vacancies in the zinc oxide structure are filled when the electron transport layer is treated with the pulsed light according to Example 1 of the present disclosure.

FIG. 3 is a schematic diagram of electron accumulation at the interface between the electron transport layer and the quantum dot light-emitting layer after the electron transport layer is treated with the pulsed light according to Example 1 of the present disclosure.

FIG. 4 is a schematic diagram showing that electron accumulation at the interface between the electron transport layer and the quantum dot light-emitting layer is alleviated after using the pulsed light to treat the electron transport layer according to Example 1 of the present disclosure.

FIG. 5 is a schematic diagram of using the pulsed light to process the electron transport layer provided in Example 1 of the present disclosure.

FIG. 6 is a schematic diagram of an in-situ reaction occurring on the surface of the electron transport layer provided in Example 4 of the present disclosure.

FIG. 7 is a schematic diagram of the electron transport layer before the surface defects of the electron transport layer are passivated provided in Example 4 of the present disclosure.

FIG. 8 is a schematic diagram showing surface defects of the electron transport layer provided in Example 4 of the present disclosure being passivated by hydroxyl groups.

FIG. 9 is a schematic diagram of using humid air to passivate the electron transport layer provided in Example 4 of the present disclosure.

FIG. 10 is a schematic diagram of using ultrasound to moisten the air environment to passivate the electron transport layer provided in Example 5 of the present disclosure.

FIG. 11 is a schematic diagram of using ultrasound to moisten the nitrogen environment to passivate the surface of the electron transport layer provided in Example 6 of the present disclosure.

FIG. 12 is a luminous efficiency-current density curve of the quantum dot light-emitting diodes provided in Examples 1 to 7 and Comparative Examples 1 to 4 of the present disclosure.

FIG. 13 is a luminous efficiency-brightness curve of the organic light-emitting diodes provided in Example 8 and Comparative Example 5 of the present disclosure.

FIG. 14 is a current density-voltage curve of the perovskite battery provided in Example 9 and Comparative Example 6 of the present disclosure.

FIG. 15 is a schematic flowchart of a method of processing a thin film according to the first embodiment of the present disclosure.

FIG. 16 is a schematic flowchart of the method of processing a thin film according to the second embodiment of the present disclosure.

FIG. 17 is a schematic flowchart of the method of processing a thin film according to the third embodiment of the present disclosure.

FIG. 18 is a schematic flowchart of the method of processing a thin film according to the fourth embodiment of the present disclosure.

FIG. 19 is a schematic flowchart of a method for preparing a light-emitting diode proposed in an embodiment of the present disclosure.

Among them, 101—electron transport layer; 102—ultrasonic device, 103—airtight container I; 104—airtight container II, 105—injection port I, 106—pulsed light; 107—injection port II; 108—defect; 109—oxygen vacancy.

### EMBODIMENTS OF THE PRESENT DISCLOSURE

The technical solutions in the present disclosure will be fully and clearly described with reference to the accompanying drawings. It is apparent that the described embodiments are only a part of the embodiments of the present disclosure, rather than all of the embodiments. Based on the embodiments in the present disclosure, all other embodiments obtained by a person skilled in the art without involving any inventive effort fall within the scope of the present disclosure.

It should be noted that the order of description of the following embodiments is not intended as a limitation of the preferred order of the embodiments. In addition, in the description of the present disclosure, the term “includes” means “includes but is not limited to”. Various embodiments of the present disclosure may exist in the form of a range. It should be understood that the description in range format is merely for convenience and brevity, and should not be construed as a rigid restrictions on the scope of the present disclosure. Therefore, it should be considered that the range description has specifically disclosed all possible sub-ranges as well as a single value within the range. For example, it should be considered that the range description from 1 to 6 has specifically disclosed sub-ranges, such as from 1 to 3, from 1 to 4, from 1 to 5, from 2 to 4, from 2 to 6, from 3 to 6, and the like, and single numbers within the ranges, such as 1, 2, 3, 4, 5, and 6, which apply regardless of the range. In addition, whenever a numeric range is indicated herein, it includes any referenced number (fraction or integer) within the referenced range.

In the present disclosure, “one or more” means one or more, and “more” means two or more. “One or more”, “at least one of the following” or similar expressions refer to any combination of these items, including any combination of single items (items) or complex items (items). For example, “at least one of a, b, or c”, or “at least one of a, b, and c”, may mean: a, b, c, a-b (i.e. a and b), a-c, b-c, or a-b-c, among them, a, b, c can be single or multiple, respectively.

Embodiments of the present disclosure provide a thin film processing method and a light-emitting diode preparation method. Each is explained in detail below. It should be noted that the order of description of the following embodiments is not intended as a limitation of the preferred order of the embodiments. In addition, in the description of the present disclosure, the term “includes” means “includes but is not limited to”. Various embodiments of the present disclosure may exist in the form of a range; it should be understood that the description in a range form is only for convenience and simplicity and should not be understood as a hard limit to the scope of the present disclosure; therefore, the range description should be considered to have specifically disclose all possible subranges as well as the single value within the range. For example, a description of a range from 1 to 10 should be considered to have specifically disclosed subranges, such as from 1 to 2, from 1 to 3, from 1 to 4, from 1 to 5, from 1 to 6, from 1 to 7, from 1 to 8, from 1 to 9, from 2 to 3, from 2 to 4, from 2 to 5, from 2 to 6, from 2 to 7, from 2 to 8, from 2 to 9, from 2 to 10, from 3 to 4, from 3 to 5, from 3 to 6, from 3 to 7, from 3 to 8, from 3 to 9, from 3 to 10, from 4 to 5, from 4 to 6, from 4 to 7, from 4 to 8, from 4 to 9, from 4 to 10, from 5 to 6, from 5 to 7, from 5 to 8, from 5 to 9, from 5 to 10, from 6 to 7, from 6 to 8, from 6 to 9, from 6 to 10, from 7 to 8, from 7 to 9, from 7 to 10, from 8 to 9, from 8 to 10, from 9 to 10, and the like, as well as single numbers in the range of numbers, such as 1, 2, 3, 4, 5, 6, 7, 8, 9 and 10, this applies regardless of the range.

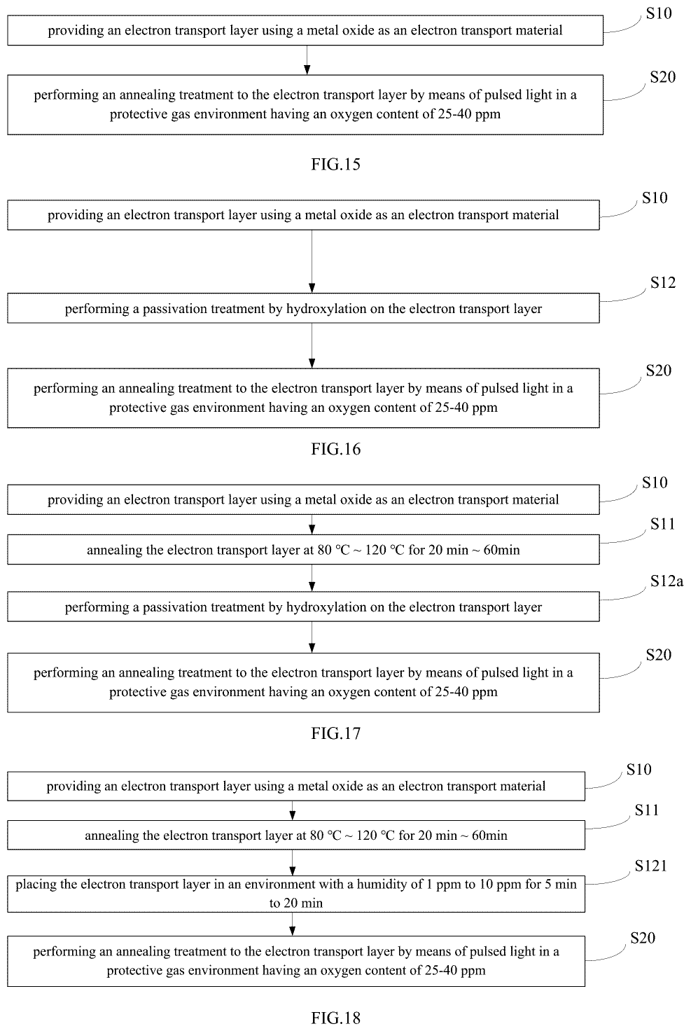

In a first aspect, an embodiment of the present disclosure provides a method of processing a thin film. Referring to FIG. 15, in an embodiment of the present disclosure, the method of processing a thin film includes:
Step S10: providing an electron transport layer using a metal oxide as an electron transport material; and
Step S20: performing an annealing treatment to the electron transport layer by means of pulsed light in a protective gas environment having an oxygen content of 25-40 ppm.

In the present disclosure, the electron transport layer is annealed by using the pulsed light in a specific oxygen atmosphere, so that the amount of electrons caused by the reduction of oxygen vamaycies in the metal oxide is reduced, so as to effectively control the electron transport and injection characteristics of the electron transport layer, and further solve the problem of charge injection imbalance of the device based on the electron transport layer. At the same time, because there will be a certain amount of moisture in the metal oxide during the deposition of the electron transport layer, a trace amount of O₂ may capture the free electrons generated by a chemical reaction between a moisture and a metal oxide under an action of the pulsed light, and convert them into O²⁻ and O⁻, thereby reducing an electron concentration of the metal oxide and a conductivity of the electron transport layer, so that an electron accumulation at the interface between the electron transport layer and the quantum dot light-emitting layer in the light-emitting diode based on the electron transport layer is alleviated.

In some embodiments, a wavelength of the pulsed light adopted in the annealing treatment ranges from 400 nm to 1200 nm. Pulsed light, also known as intense pulsed light (IPL), is light emitted by high-intensity xenon lamps with wavelengths ranging from about 400 nm to 1200 nm, which may be used for annealing or sintering of metals or oxide semiconductors. It should be noted that, in some embodiments of the present disclosure, a frequency of the pulsed light ranges from 1.5 Hz to 4 Hz, and an energy of the pulsed light ranges from 1.20 J/cm² to 2.0 J/cm². And further, the frequency of the pulsed light is 2 Hz, and the energy of the pulsed light is 1.58 J/cm². When the pulsed light is used for the annealing treatment, a time of the annealing treatment is short, so an efficiency of the annealing treatment is high; the pulsed light has a pulse time ranging from a few milliseconds to microseconds per pulse, so thermal damage may be reduced, and at the same time, it may also provide energy for oxygen in the protective gas environment to fill the oxygen vamaycies of metal oxides.

In some embodiments, the metal oxide is selected from one or more of ZnO, TiO₂, SnO₂, Ta₂O₃, ZrO₂, NiO, TiLiO, ZnAlO, ZnSnO, ZnLiO, and InSnO. Wherein TiLiO is lithium-doped titanium oxide, ZnAlO is aluminum-doped zinc oxide, ZnSnO is tin-doped zinc oxide, ZnLiO is lithium-doped zinc oxide, and InSnO is tin-doped indium oxide.

In some embodiments, referring to FIG. 17, after providing an electron transport layer using a metal oxide as an electron transport material, and before performing an annealing treatment to the electron transport layer by means of pulsed light, the method further includes step S11: annealing the electron transport layer at 80° C.˜ 120° C. for 20 min˜ 60 min.

It should be noted that in the present disclosure, the electron transport layer is obtained by a film-forming process using an electron transport material based on a metal oxide as a raw material. In some embodiments, the preparation of the electron transport layer includes: depositing a solution of a metal oxide on a semi-finished device to obtain an electron transport layer. Among them, the method of depositing the metal oxide in the present disclosure may be chemical methods or physical methods, wherein chemical methods include but are not limited to a chemical vapor deposition method, a continuous ionic layer adsorption and reaction method, and a co-deposition method; physical methods include but are not limited to a spin coating method, a transfer printing method, a printing method, a scraping coating method, a dipping and drawing method, a spray coating method, a roll coating method, a casting method, a slit coating method, and a strip coating method.

After the metal oxide is deposited on a semi-finished device, an electron transport layer is formed. At this time, the electron transport layer is unstable, and the crystallization is incomplete, and there are many internal defects in the electron transport layer. Therefore, the electron transport layer needs to be solidified. After annealing the electron transport layer at 80° C.˜ 120° C. for 20 min˜ 60 min, the internal defects in the electron transport layer may be reduced, and a stable and fully crystallized electron transport layer may be formed.

The solvent used in the solution of the metal oxide is a polar solvent, which is selected from one or more of methanol, ethanol, and water.

The semi-finished device is a substrate with electrodes deposited or a substrate with electrodes and functional layers deposited. In some embodiments, the functional layer includes one or more layers of an electron injection layer, an electron transport layer, and a hole barrier layer, and the electron transport layer is deposited on the surface of the electron injection layer or the surface of the hole barrier layer.

In some embodiments, the functional layer includes a quantum dot light-emitting layer on which the electron transport layer is deposited.

In some embodiments, an interface modification layer is also disposed on the functional layer, and the electron transport layer is deposited on the surface of the interface modification layer.

Referring to FIG. 16, in some embodiments, before performing the annealing treatment to the electron transport layer by means of the pulsed light, it further includes step S12: performing a passivation treatment by hydroxylation on the electron transport layer.

Referring to FIG. 17, in other embodiments, after annealing the electron transport layer at 80° C.˜ 120° C. for 20 min˜ 60 min, and before performing the annealing treatment to the electron transport layer by means of the pulsed light, the method further includes step S12a: performing a passivation treatment by hydroxylation on the electron transport layer.

After the metal oxide is prepared by the film-forming process, the surface of the electron transport layer has O²⁻, O⁻, M²⁺, and M⁺ (M represents the metal element in the metal oxide) and the like, so in a process of the passivation treatment by hydroxylation, the hydroxyl group provided by the compound existing in the environment of the electron transport layer may undergo a series of in-situ reactions with the ions on the surface of the electron transport layer, so that the defects on the surface of the metal oxide are passivated, thereby reducing the leakage of holes to the metal oxide.

Referring to FIG. 18, in some embodiments, the passivation treatment by hydroxylation includes:

step S121: placing the electron transport layer in an environment with a humidity of 1 ppm to 10 ppm for 5 min to 20 min. Defects on the surface of metal oxides are passivated by hydroxyl groups. Among them, the humidity should not be too high or too low, so that it may provide sufficient hydroxyl groups for the passivation treatment of the electron transport layer, and at the same time avoid the impact of water vapor providing humidity on the electron transport layer due to too high humidity.

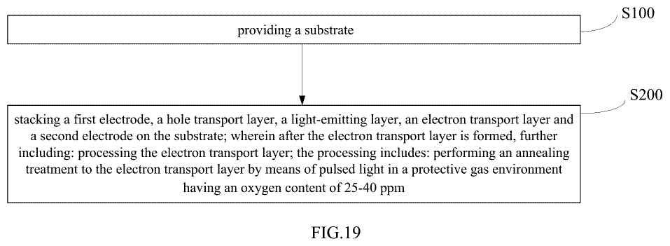

In order to better understand the present disclosure, an embodiment of the present disclosure also provides a method for preparing a light-emitting diode, referring to FIG. 19, the method includes:
step S100: providing a substrate; and
step S200: stacking a first electrode, a hole transport layer, a light-emitting layer, an electron transport layer and a second electrode on the substrate; wherein after the electron transport layer is formed, further including: processing the electron transport layer; the processing includes: performing an annealing treatment to the electron transport layer by means of pulsed light in a protective gas environment having an oxygen content of 25-40 ppm.

Step of stacking the first electrode, the hole transport layer, the light-emitting layer, the electron transport layer and the second electrode on the substrate means that the first electrode, the hole transport layer, the light-emitting layer, the electron transport layer and the second electrode are formed on the surface of the substrate in a stack arrangement. A lamination order of each of layers is not limited. The first electrode, the hole transport layer, the light-emitting layer, the electron transport layer and the second electrode may be formed, or the first electrode, the electron transport layer, the light-emitting layer, the hole transport layer and the second electrode also may be formed.

In some embodiments, the first electrode, the hole transport layer, the light-emitting layer, the electron transport layer, and the second electrode are sequentially stacked; the processing is performed before the second electrode is formed; or
the first electrode, the electron transport layer, the light-emitting layer, the hole transport layer and the second electrode are sequentially stacked, and the processing is performed before the light-emitting layer is formed.

The light-emitting diode in the present disclosure may be an upright light-emitting diode or an inverted light-emitting diode. When the light-emitting diode is the upright light-emitting diode, the upright light-emitting diode includes the first electrode, the hole transport layer, the light-emitting layer, the electron transport layer and the second electrode arranged in a stack, the first electrode is an anode, the second electrode is a cathode, and the anode is arranged on the substrate; when the light-emitting diode is the inverted light-emitting diode, the inverted light-emitting diode includes the first electrode, the electron transport layer, the light-emitting layer, the hole transport layer and the second electrode, the first electrode is the cathode, the second electrode is the anode, and the cathode is arranged on the substrate.

In some embodiments, a time of annealing treatment ranges 2 min to 5 min, thereby achieving efficient treatment of the electron transport layer while avoiding thermal damage of the electron transport layer due to an excessively long pulsed light annealing time.

In some embodiments, the water vapor concentration in the protective gas environment is below 0.1 ppm, the environment in which the annealing treatment of the electron transport layer is performed is kept dry, the moisture in the obtained electron transport layer is reduced, and the influence of moisture on the device based on the electron transport layer is reduced.

In some embodiments, the protective gas for annealing the electron transport layer with pulsed light is selected from one or more of nitrogen gas and inert gas (such as helium gas, argon gas, and neon gas).

In some embodiments, after the hole transport layer is formed and before the processing, the electron transport layer is placed in an environment with a humidity of 1 ppm to 10 ppm for 5 min to 20 min;
wherein, the humidity may be provided by one or more of distilled water, deionized water, high purity water, and ultrapure water.

In the present disclosure, water is used to provide a humidity environment, the electron transport layer is treated with water vapor, and the passivation of the electron transport layer based on metal oxide is realized by using the hydroxyl group of water. This is because the structure of water molecules is simple and volatile, so it is not suitable to remain in the electron transport layer after performing the passivation treatment by hydroxylation on the electron transport layer; and water is chemically neutral, the ions produced by ionization are H⁺, and OH⁻, and their acidity is weak, which has little impact on the electron transport layer. Preferably, the water is deionized water. Using deionized water to perform the passivation treatment by hydroxylation on the electron transport layer may avoid changes in the conductivity of the water due to other ions contained in the water, thereby causing the device charge imbalance based on the electron transport layer to occur or aggravate.

Among them, the environment with a humidity of 1 to 10 ppm may be an air environment or a protective gas environment.

In some embodiments, the environment with a humidity of 1 to 10 ppm is a protective gas environment. The protective gas may be nitrogen or inert gas (such as argon, helium, and argon) to avoid the influence of other gas components on the electron transport layer, thereby improving the device based on the electron transport layer to have better electrical performance and working life; in particular, oxygen may be avoided from entering the electron transport layer and causing more defects, thereby affecting the conductivity of the electron transport layer. At the same time, using an oxygen-free protective gas environment with the humidity of 1 to 10 ppm may also improve the surface roughness of the electron transport layer.

In some embodiments, the water may be optionally evaporated directly at room temperature so that the humidity in the environment reaches 1 to 10 ppm, or it may be optionally placed in the treatment space so that the humidity in the environment reaches 1 to 10 ppm by ultrasound.

In some embodiments, the humidity in the environment is adjusted by an ultrasonic device, so that the humidity in the environment is adjusted in the range of 1 to 10 ppm; the ultrasonic device may be selected from ultrasonic equipment such as an ultrasonic humidifier, an ultrasonic atomizer and the like, which may vaporize or atomize water.

The above-mentioned method of processing the electron transport layer may be applicable to any device including an electron transport layer and a hole transport layer, and the carrier mobility of the electron transport layer is higher than that of the hole transport layer, such as a perovskite battery and a light-emitting diode, wherein the light-emitting diode may be an inorganic light-emitting diode, an organic light-emitting diode, and a Quantum dot light-emitting diode (QLED). The electron transport layer obtained by using the above post-processing method is especially suitable for QLED.

The above-mentioned method of processing the electron transport layer may be applicable to any device including an electron transport layer and a hole transport layer, and the carrier mobility of the electron transport layer is higher than that of the hole transport layer, such as a perovskite battery and a light-emitting diode, wherein the light-emitting diode may be an inorganic light-emitting diode, an organic light-emitting diode, and a Quantum dot light-emitting diode (QLED). The electron transport layer obtained by using the above post-processing method is especially suitable for QLED.

However, with the development of quantum dot synthesis and device structure, the external quantum efficiency of QLED has increased from 10% to 20%; and laboratory-scale devices with a half-width emission spectrum of approximately 25 nm have been proven to be suitable for all trichromatic full-color displays. At present, after years of research and development, the efficiency of QLED is very close to that of organic light-emitting diodes, and its color saturation and manufacturing cost are far superior to OLED. In addition, due to the high compatibility of QLED with printed displays, more and more display manufacturers have incorporated QLED into their development blueprint.

At present, metal oxide has become a commonly used electron transmission and injection layer material in QLED. Among them, zinc oxide nanoparticles have excellent characteristics such as high mobility, high transparency, high conductivity and adjustable energy band. Because their conduction band energy level is conducive to the injection of electrons from the cathode to the quantum dots, and their deep valence band energy level may also play an effective role in blocking holes, zinc oxide nanoparticles are particularly commonly used in the electron transport layer and electron transport layer in QLEDs. Therefore, in QLED, the problem that the electron mobility of the electron transport layer is higher than that of the hole transport layer, and the electron injection barrier in the electron transport layer is much smaller than that in the hole transport layer is common, and in the process of preparing QLED, the problem that the electron transport layer is affected by H₂O and O₂ also needs to be solved urgently. The thin film processing method provided by the present disclosure may not only reduce the electron amount of the electron transport layer, improve the problem of carrier imbalance of the QLED, but also reduce the influence of H₂O and O₂ on the electron transport layer during the QLED preparation process, so it is suitable for the post-processing method of the electron transport layer which the present disclosure provided.

In some embodiments, the substrate may be a rigid substrate or a flexible substrate. A material of the rigid substrate may be selected from one or more of glass and metal foil; a material of the flexible substrate is selected from one or more of polyethylene terephthalate (PET), polyethylene terephthalate (PEN), polyether ether ketone (PEEK), polystyrene (PS), polyether sulfone (PES), polycarbonate (PC), polyaryl acid ester (PAT), polyarylate (PAR), polyimide (PI), polyvinyl chloride (PV), polyethylene (PE), polyvinylpyrrolidone (PVP), and textile fibers. The electrode may be a cathode or an anode. Wherein the material of the cathode may be selected from one or more of Al, Ag, Au, Cu, Mo and their alloys; the material of the anode may be selected from one or more of ITO, FTO, and ZTO.

In some embodiments, a material of the hole transport layer may be an organic material having a hole transport capability or an inorganic material having a hole transport function. Wherein the organic material having the hole transport capacity may be selected from one or more of poly (9, 9-dioctylfluorene-CO—N-(4-butylphenyl) diphenylamine), poly(N-vinylcarbazole), poly[N,N′-bis(4-butylphenyl)-N,N′-bisphenylbenzidine], poly[(9,9-dioctylfluorenyl-2,7-diyl)-co-(N,N′-diphenyl)-N,N′di(p-butyl-oxy-phenyl)-1, 4-diaMinobenzene) 4,4′,4″-Tris(carbazol-9-yl)-triphenylamine, 4,4′-Di(9H-carbazol-9-yl)-1,1′-biphenyl, N,N′-bis(3-methylphenyl)-N,N′-diphenyl-benzidine, 15N,N′-Bis(1-naphthalenyl)-N,N′-bisphenyl-(1,1′-biphenyl)-4,4′-diamine, graphene, and C60; the inorganic material having hole transport capability may be selected from one or more of NiOₓ, MoOₓ, WOₓ, CrOₓ, CuO, MoSₓ, MoSeₓ, WSₓ, WSeₓ, and CuS. It should be noted that x here is a positive number, and x may be selected from values such as 0.5, 1, 1.5, 2, 2.5, and 3.

In some embodiments, a material of the hole injection layer may be selected from one or more of PEDOT:PSS, CuPc, F4-TCNQ, HATCN, a transition metal oxide, and a transition metal chalcogenide compound. Wherein the transition metal oxide is selected from one or more of NiOₓ, MoOₓ, WOₓ, CrOₓ, and CuO. The metal chalcogenide compound is selected from one or more of MoSₓ, MoSeₓ, WSₓ, WSeₓ, and CuS. It should be noted that x here is a positive number, and x may be selected from values such as 0.5, 1, 1.5, 2, 2.5, and 3.

It should be noted that a material of the light-emitting layer may be a direct band gap compound semiconductor having light-emitting ability, such as a perovskite semiconductor.

In some embodiments, direct band gap compound semiconductors capable of luminescence include, but are not limited to, one or more of a group II-VI compound, a group III-V compound, a group II-V compound, a group III-VI compound, a group IV-VI compound, a group I-III-VI compound, a group II-IV-VI compound, or a group IV elemental substance. Specifically, the Group II-VI compound is selected from one or more of CdS, CdSe, CdTe, ZnS, ZnSe, ZnTe, HgS, HgSe, HgTe, PbS, PbSe, PbTe, and other binary, ternary, and quaternary II-VI semiconductor nanocrystals; the III-V group compound is selected from one or more of GaP, GaAs, InP, InAs and other binary, ternary and quaternary III-V semiconductor nanocrystals; the group II-V compound is selected from one or more of GaP, GaAs, InP, InAs, and other binary, ternary, and quaternary III-V semiconductor nanocrystals.

In some embodiments, the perovskite type semiconductor may be a doped or non-doped inorganic perovskite type semiconductor, or an organic-inorganic hybrid perovskite type semiconductor. Specifically, the general structural formula of the inorganic perovskite type semiconductor in an embodiment of the present disclosure may be AMX₃. Among them, A is a Cs⁺, M is a divalent metal cation, and X is a halogen anion. Divalent metal cations include, but are not limited to, Pb²⁺, Sn²⁺, Cu²⁺, Ni²⁺, Cd²⁺, Cr²⁺, Mn²⁺, Co²⁺, Fe²⁺, Ge²⁺, Yb²⁺, and Eu²⁺; halogen anions include, but are not limited to, Cl⁻, Br⁻, and I⁻; specifically, the general structural formula of the organic-inorganic hybrid perovskite type semiconductor in an embodiment of the present disclosure may be BMX₃. B is an organic amine cation, M is a divalent metal cation, and X is a halogen anion. Organic amine cations include, but are not limited to, CH₃(CH₂)ₙ₋₂NH₃⁺ (n≥2) or CH₃(CH₂)ₙ₋₂NH₃⁺ (n≥2). When n=2, the inorganic metal halide octahedron MX₆⁴⁻ is connected by a cotopical way, the metal cation M is located in the body center of the halogen octahedron, and the organic amine cation B is filled in the voids between the octahedra, forming an infinitely extended three-dimensional structure; when n>2, the inorganic metal halide octahedron MX₆⁴⁻ connected in a cotopical manner extends in the two-dimensional direction to form a layered structure, and an organic amine cation bilayer (protonated monoamine) or an organic amine cation monolayer (protonated bisamine) is inserted between the layers, and the organic layer and inorganic layer overlap each other to form a stable two-dimensional layered structure; divalent metal cations include, but are not limited to, Pb²⁺, Sn²⁺, Cu²⁺, Ni²⁺, Cd²⁺, Cr²⁺, Mn²⁺, Co²⁺, Fe²⁺, Ge²⁺, Yb²⁺, and Eu²⁺; X is a halogen anion, including but not limited to Cl⁻, Br⁻, and I⁻.

In some embodiments, a method of depositing the first electrode, the hole transport layer, the light-emitting layer, and the second electrode in the present disclosure may be chemical methods or physical methods, wherein chemical methods include but are not limited to electroplating method, chemical vapor deposition method, continuous ion layer adsorption and reaction method, and co-deposition method; physical method include but are not limited to spin coating method, transfer printing method, printing method, scraping coating method, dipping and drawing method, spray coating method, roll coating method, casting method, slit coating method, and strip coating method.

An embodiment of the present disclosure also provides a light-emitting diode, which is prepared by the preparation method described above.

It should be noted that the drawings attached to embodiments of the present disclosure only refer to the structures involved in embodiments of the present disclosure, and other structures may be referred to the usual design.

The present disclosure will be described in detail below by means of embodiments.

### EXAMPLE 1

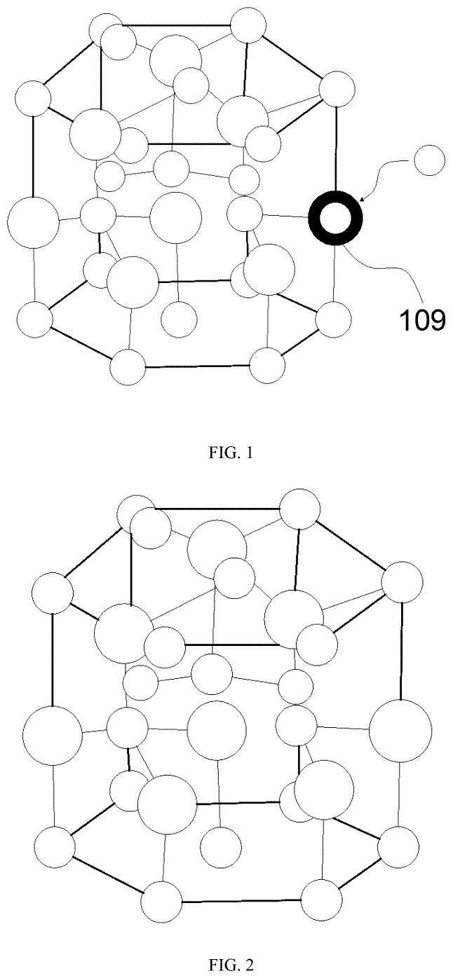

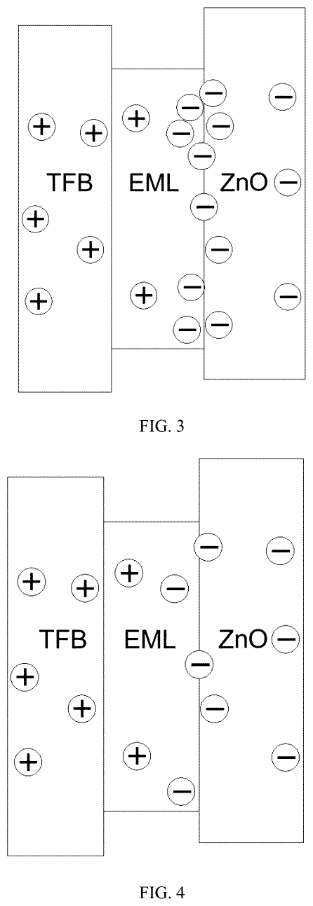

A method of preparing a light-emitting diode includes:
S1: providing an ITO substrate and a PEDOT:PSS aqueous solution, spin-coating the PEDOT:PSS aqueous solution on the ITO substrate at a speed of 5000 rad/min for 30 s, and then heating and annealing at 150° C. for 15 min to complete the preparation of a hole injection layer;
S2: providing a TFB dichlorobenzene solution with a TFB concentration of 8 mg/mL, placing a piece obtained in S1 in a glove box, adding the TFB dichlorobenzene solution dropwise on the hole injection layer, and spin-coating at a speed of 3000 rad/min for 30 s, and then heating and annealing at 100° C. for 30 min to complete the preparation of a hole transport layer;
S3: providing a quantum dot solution with a concentration of 20 mg/ml of CdSe, adding the quantum dot solution dropwise on the hole transport layer, and spin-coating at a rotational speed of 2000 rad/min for 30 seconds, and then heating and annealing at 150° C. for 15 min to complete the preparation of a quantum dot light-emitting layer;
S4: providing a ZnO solution with a concentration of 30 mg/mL of ZnO, spin-coating at a speed of 3000 rad/min for 30 s, and then heating and annealing at 80° C. for 30 min to complete the preparation of the electron transport layer;
S5: as shown in FIG. 5, placing a piece containing the electron transport layer 101 obtained in S4 into an airtight container II 104 in which the protective gas environment is nitrogen gas environment and the oxygen concentration in the nitrogen gas environment is 30 ppm, radiating the ZnO layer with pulsed light 106 for 120 s, as shown in FIG. 1 and FIG. 2, so that the oxygen vacancies 109 in the zinc oxide structure are filled with oxygen, and as shown in FIG. 3 and FIG. 4, relieving the electron accumulation at the interface between the electron transport layer and the quantum dot light-emitting layer during the operation of the device; and
S6: under the condition that the vacuum degree is not higher than 3×10⁻⁴ Pa, the aluminum is evaporated at a speed of 1 angstrom/second for 100 seconds by thermal evaporation, so as to obtain an aluminum layer with a thickness of 10 nm, so as to obtain a top-emitting upright quantum dot light-emitting diode A.

In an embodiment, an injection port II 107 is provided in the airtight container II 104 for injecting the protective gas having an oxygen concentration of 30 ppm. However, it should be noted that in the present disclosure, the airtight container II is not necessarily provided with an injection port II for gas injection, and the protective gas with an oxygen concentration of 25 to 40 ppm may be injected or realized in other ways.

### EXAMPLE 2

Example 2 relates to a method of preparing a light-emitting diode. In this embodiment, the oxygen concentration in the protective gas environment of the airtight container II of S5 is 25 ppm; and the rest is the same as in Example 1, and a top-emitting upright quantum dot light-emitting diode B is prepared.

### EXAMPLE 3

Example 3 relates to a method of preparing a light-emitting diode. In this embodiment, the oxygen concentration in the protective gas environment of the airtight container II of S5 is 40 ppm; and the rest is the same as in Example 1, and a top-emitting upright quantum dot light-emitting diode C is prepared.

### EXAMPLE 4

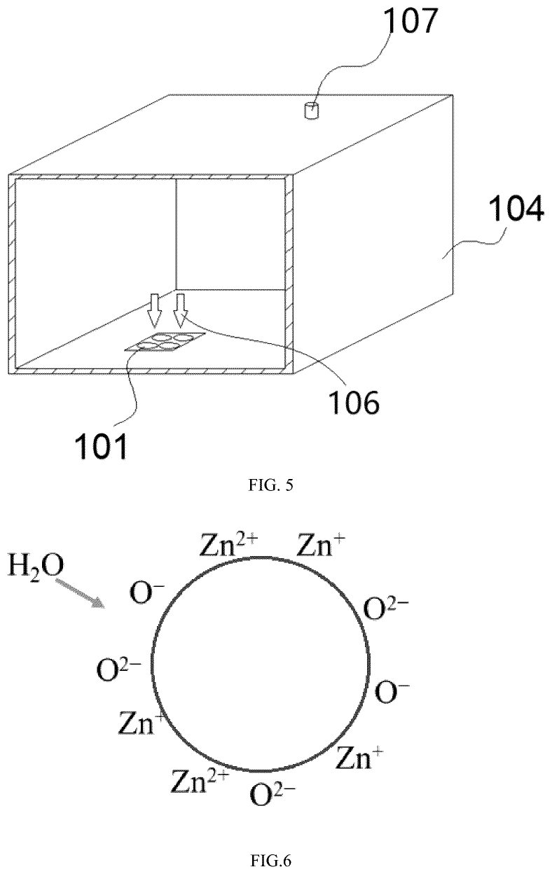

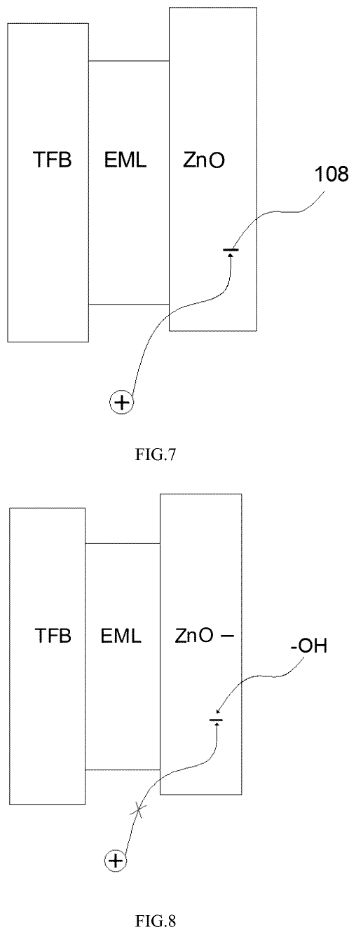

A method of preparing a light-emitting diode includes:
S1: providing an ITO substrate and a PEDOT:PSS aqueous solution, spin-coating the PEDOT:PSS aqueous solution on the ITO substrate at a speed of 5000 rad/min for 30 s, and then heating and annealing at 150° C. for 15 min to complete the preparation of a hole injection layer;
S2: providing a TFB dichlorobenzene solution with a TFB concentration of 8 mg/mL, placing a piece obtained in S1 in a glove box, adding the TFB dichlorobenzene solution dropwise on the hole injection layer, and spin-coating at a speed of 3000 rad/min for 30 s, and then heating and annealing at 100° C. for 30 min to complete the preparation of a hole transport layer;
S3: providing a quantum dot solution with a concentration of 20 mg/ml of CdSe, adding the quantum dot solution dropwise on the hole transport layer, and spin-coating at a rotational speed of 2000 rad/min for 30 seconds, and then heating and annealing at 150° C. for 15 min to complete the preparation of a quantum dot light-emitting layer;
S4: spin-coating a ZnO solution with a concentration of 30 mg/mL of ZnO at a speed of 3000 rad/min for 30 s, and then heating and annealing at 80° C. for 30 min to complete the preparation of the electron transport layer;
S5: as shown in FIG. 9, taking out the piece containing the electron transport layer 101 from the glove box and placing it in an airtight container I 103 filled with air, where a humidity in the airtight container I 103 is 10 ppm, and placing it for 5 minutes;
as shown in FIGS. 6 to 8, there are O²⁻, O⁻, Zn²⁺, and Zn⁺ plasma on the surface of the electron transport layer based on zinc oxide, and the water and the ions on the surface of the electron transport layer undergo in-situ reactions such as Zn⁺+O²⁻+H₂O→Zn+—OH+OH⁻+e⁻; at the same time, water dissociates in the form of —H and —OH radicals, adsorbs on the surface of zinc oxide, and generates free electrons, realizing the passivation of surface defects 108 of zinc oxide, thereby reducing hole leakage into zinc oxide.
the passivated wafer is then placed in the airtight container II 104 with a protective gas environment and an oxygen concentration of 30 ppm in the protective gas environment, and the ZnO layer is irradiated with pulsed light 106 for 120 s; and
S6: under the condition that the vacuum degree is not higher than 3×10⁻⁴ Pa, the aluminum is evaporated at a speed of 1 angstrom/second for 100 seconds by thermal evaporation, so as to obtain an aluminum layer with a thickness of 10 nm, so as to obtain a top-emitting upright quantum dot light-emitting diode A.

In the present embodiment, the airtight container 1103 is provided with an injection port 1105 for injecting air with a humidity of 10 ppm. However, it should be noted that in the present disclosure, the airtight container I is not necessarily provided with an injection port I for gas injection, and the environment adopted by the airtight container I with a humidity of 1 to 10 ppm may be injected or realized in other ways.

### EXAMPLE 5

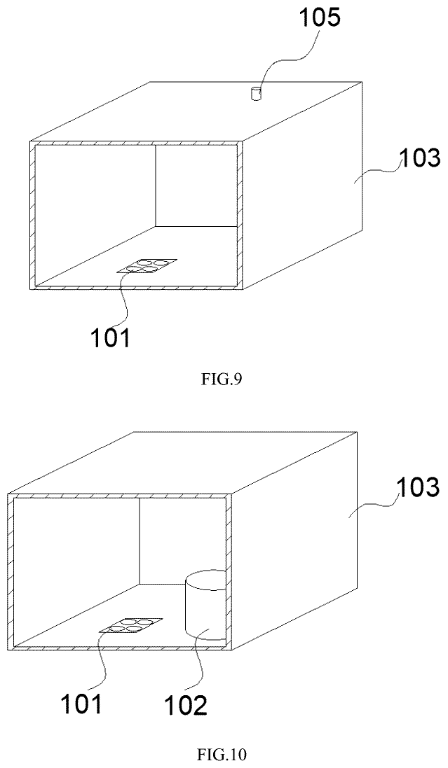

Example 5 relates to a method of preparing a light-emitting diode. As shown in FIG. 10, 100 mL of water is placed in the airtight container I of S5 in this embodiment, and the humidity in the airtight container I is ultrasound to 10 ppm by an ultrasonic device 102; and the rest is the same as in Example 4, and a top-emitting upright quantum dot light-emitting diode E is prepared.

### EXAMPLE 6

Example 6 relates to a method of preparing a light-emitting diode. As shown in FIG. 11, the gas environment of the airtight container 1103 in S5 in this embodiment is a nitrogen environment, 100 ml of water is placed in the airtight container 1103, and the humidity in the airtight container I is ultrasound to 10 ppm by an ultrasonic device 102; and the rest is the same as in Example 4, and a top-emitting upright quantum dot light-emitting diode F is prepared.

### EXAMPLE 7

Example 7 relates to a method of preparing a light-emitting diode. The solution used for spin-coating in S4 of this embodiment is NiO solution, and the rest is the same as in Example 4, and a top-emitting upright quantum dot light-emitting diode G is prepared.

### EXAMPLE 8

Example 8 relates to a method of preparing a light-emitting diode. In S3 of this embodiment, the solution used for spin-coating is an organic light-emitting material TADF, which is spin-coated at a speed of 2500 rad/min for 30 seconds, annealed at 80° C. for 15 minutes, and the rest is the same as in Example 1, and a top-emitting upright organic light-emitting diode H is prepared.

### EXAMPLE 9

A preparation of a perovskite cell includes the following steps:
S1: providing an ITO substrate and a SnO₂ solution, spin-coating the SnO₂ solution on the ITO substrate at a speed of 4000 rad/min for 30 s. and then heating and annealing at 120° C. for 20 min;
S2: In S5 of this embodiment, the gas environment of the airtight container I 103 is a nitrogen environment, 100 ml of water is placed in the airtight container I 103, and the humidity in the airtight container I is 10 ppm by ultrasound through the ultrasound device 102. After that, the SnO₂ solution was placed for 5 minutes and treated with the pulsed light for 120 seconds to complete the preparation of the electron transport layer.
S3: providing a PbI₂ and FAI precursor solution with a molar ratio of 2:1, placing the piece into a glove box, dropping a TFB dichlorobenzene solution on the hole injection layer, and spin-coating at a speed of 3500 rad/min for 30 seconds; and then heating and annealing at 110° C. for 20 minutes to complete the preparation of the active layer;
S4: providing a Spiro-OMeTAD solution with a concentration of 73 mg/mL, dropping the hole transport layer solution on the active layer, and spin-coating at a speed of 1500 rad/min for 30 seconds; and then heating and annealing at 130° C. for 20 minutes to complete the preparation of hole transport layer;
S5: under the condition that the vacuum degree is not higher than 3×10⁻⁴ Pa, the aluminum is evaporated at a speed of 1 angstrom/second for 100 seconds by thermal evaporation, so as to obtain an aluminum layer with a thickness of 10 nm, so as to obtain a perovskite solar cells.

### COMPARATIVE EXAMPLE 1

Compared with Example 1, in S4 of Comparative Example 1, after spin-coating the ZnO solution, heating at 80° C. for 30 minutes, and then performing S6, the rest is the same as in Example 1, and a top-emitting upright quantum dot light-emitting diode DB1 is prepared.

### COMPARATIVE EXAMPLE 2

Compared with Example 4, in S4 of Comparative Example 2, after spin-coating the ZnO solution, heating at 80° C. in a dry inert gas environment for 20 minutes, and then performing S5, the rest is the same as in Example 4, and a top-emitting upright quantum dot light-emitting diode DB2 is prepared.

### COMPARATIVE EXAMPLE 3

Compared with Example 1, in S5 of Comparative Example 3, the oxygen concentration in the protective gas environment of the airtight container II is 20 ppm; the rest is the same as in Example 1, and a top-emitting upright quantum dot light-emitting diode DB3 is prepared.

### COMPARATIVE EXAMPLE 4

Compared to Example 1, in S5 of Comparative Example 4, the oxygen concentration in the protective gas environment of the airtight container II is 45 ppm; the rest is the same as in Example 1, and a top-emitting upright quantum dot light-emitting diode DB4 is prepared.

### COMPARATIVE EXAMPLE 5

Compared with Example 8, in S4 of Comparative Example 5, after spin-coating the ZnO solution, heating at 80° C. for 30 minutes, and then performing S5, the rest is the same as in Example 1, and a upright organic light-emitting diode DB5 is prepared.

### COMPARATIVE EXAMPLE 6

Compared with Example 9, in S4 of Comparative Example 6, after spin-coating the ZnO solution, heating at 80° C. for 30 minutes, and then performing S5, the rest is the same as in Example 1, and a perovskite battery DB6 is prepared.

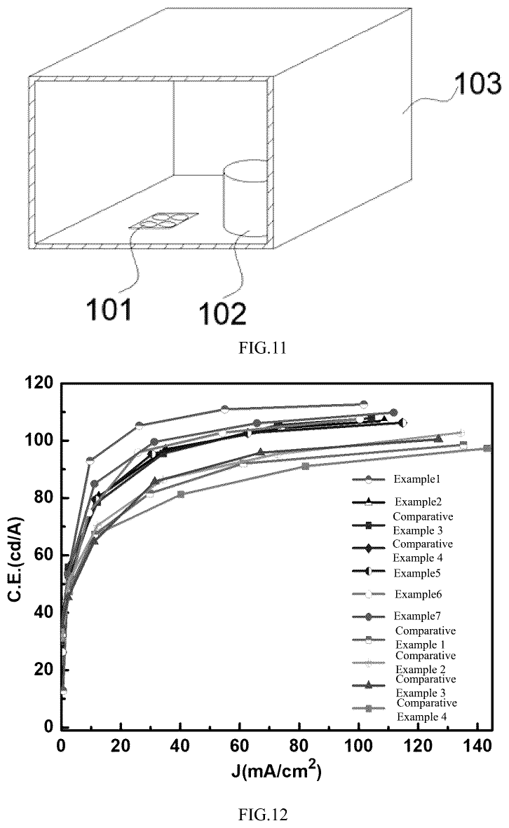

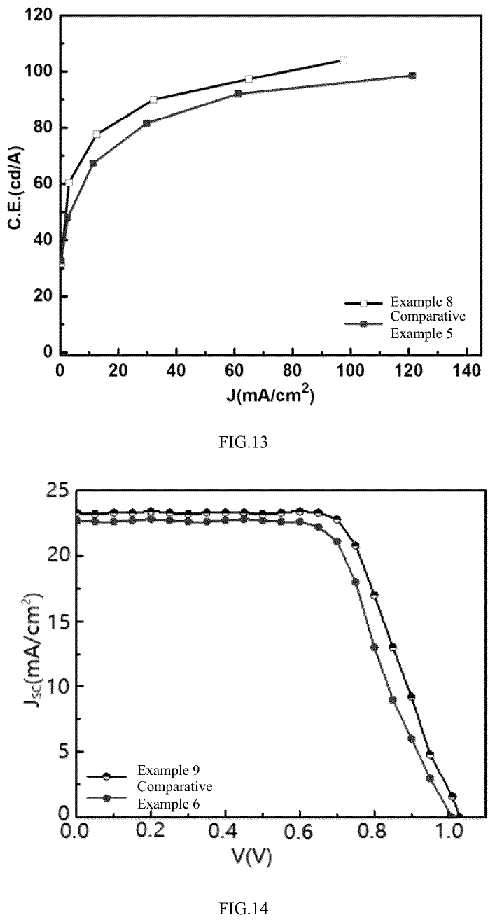

The current density-voltage curves and luminous efficiency-luminance curves of the top-emitting light-emitting diodes obtained from Examples 1 to 8 and Comparative Examples 1 to 5 were tested, respectively, and the specific test results are shown in FIGS. 12 and 13.

As shown in FIG. 12, the oxygen concentration in the protective gas environment of the post-processing method provided by the present disclosure is preferably 25 to 40 ppm, and if the oxygen concentration is too low, the lattice constant of the metal oxide will be too large and the crystal grain will be too small, thereby causing the film structure to be insufficiently compact; if the oxygen concentration is too high, there will be too many acceptor defects such as metal ion vacancies (VM), oxygen ions in the position of metal ions (OM), or oxygen ions in the lattice gap (Oi) in the electron transport layer, thereby causing the brightness of the light-emitting diode based on the electron transport layer to decrease.

As shown in FIG. 13, when the electron transport layer is processed by the processing method provided in the present disclosure, the obtained organic light-emitting diode has a small current density, which proves that the leakage current of the organic light-emitting diode is small and the device stability is good. It may be seen that the thin film processing method provided in the present disclosure may improve the stability of the electron transport layer, thereby improving the stability of the light-emitting diode based on the electron transport layer.

The brightness and working life of the top-emitting upright light-emitting diodes obtained from Examples 1 to 7 and Comparative Example 1 to 4 under the constant current drive of 2 mA are tested respectively, wherein L (cd/m²) represents the highest brightness of the device; T95 (h) and T80 (h) represent the time taken for the device to decay to 95% and 80% of brightness under constant current drive of 2 mA, respectively; T95_1K (h) and T80_1K (h) indicate the time required for the device to decay to 95% and 80% of the brightness when the brightness is 1000 nit. The specific test results are shown in Table 1:

TABLE 1

| | L | T80 | T80_1K | T95 | T95_1K |
|---|---|---|---|---|---|
| | (cd/m²) | (h) | (h) | (h) | (h) |
| Example 1 | 95958 | 19.90 | 48926.31 | 6.52 | 7825.61 |
| Example 2 | 86539 | 17.89 | 31214.08 | 4.39 | 6663.01 |
| Example 3 | 71903 | 15.98 | 25958.44 | 3.94 | 5511.89 |
| Example 4 | 62083 | 13.65 | 26325.35 | 3.42 | 6086.97 |
| Example 5 | 92057 | 17.53 | 38531.60 | 5.54 | 7264.32 |
| Example 6 | 93568 | 18.00 | 35126.53 | 5.86 | 7361.80 |
| Example 7 | 84485 | 11.99 | 28647.56 | 3.01 | 5364.96 |
| Comparative Example1 | 52671 | 12.16 | 22186.23 | 2.22 | 4163.53 |
| Comparative Example2 | 54652 | 13.45 | 24558.84 | 2.45 | 4621.38 |
| Comparative Example3 | 53982 | 14.21 | 22186.23 | 2.89 | 4450.94 |
| Comparative Example 4 | 54028 | 13.59 | 19123.46 | 2.62 | 4936.40 |

The brightness and operating life of the upright organic light-emitting diodes obtained in Example 8 and Comparative Example 5 under the constant current drive of 2 mA are respectively tested. The specific test results are shown in Table 2:

TABLE 2

| | L | T80 | T80_1K | T95 | T95_1K |
|---|---|---|---|---|---|
| | (cd/m²) | (h) | (h) | (h) | (h) |
| Example 8 | 56786 | 12.84 | 28472.68 | 3.54 | 4915.69 |
| Comparative Example 5 | 50689 | 11.56 | 25146.34 | 2.97 | 4682.35 |

It may be seen from Table 1 and Table 2 that after the electron transport layer in the light-emitting diode is processed by the processing method provided in the present disclosure, the brightness of the light-emitting diode is higher, and the time of the brightness decays to 80% and 95% under the constant current drive of 2 mA is longer, which proves that the thin film processing method provided in the present disclosure may improve the electrical performance of the electron transport layer, and further improve the electrical performance and service life of the light-emitting diode based on the electron transport layer. At the same time, it may also be seen from Table 1 and Table 2 that compared with the light-emitting diodes obtained by directly annealing the electron transport layer with the pulsed light, the brightness of the light-emitting diodes obtained by first passivating the electron transport layer with hydroxyl groups and then annealing with the pulsed light has decreased; However, compared with the light-emitting diodes not treated by the post-processing method provided in the present disclosure, the light-emitting diodes based on the electron transport film layer being passivated by hydroxyl groups and then annealed by the pulsed light have higher brightness and longer service life. It may be seen that hydroxyl passivation of the electron transport layer based on the metal oxide may reduce the leakage of holes in the electron transport layer, thereby improving the service life of the light-emitting diode based on the electron transport layer.

The perovskite solar cell performance and current density-voltage curves obtained by Example 9 and Comparative Example 6 were tested respectively, and the specific test results are shown in Table 3 and FIG. 14. Wherein, V_{oc} is the solar cell circuit voltage, and J_{sc} is the short-circuit current density; FF is the fill factor; PCE is photoelectric conversion efficiency.

TABLE 3

| | V_{oc}[V] | J_{sc}[mA cm⁻²] | FF | PCE (%) |
|---|---|---|---|---|
| Example 9 | 1.10 | 23.3 | 0.860 | 22.1 |
| Comparative Example6 | 1.13 | 22.7 | 0.780 | 20.0 |

It may be seen from Table 3 and FIG. 14 that after the electron transport layer in the perovskite solar cell is processed by the processing method provided in the present disclosure, the circuit voltage of the perovskite solar cell obtained is slightly reduced, the fill factor is significantly increased, the short-circuit current density is also increased, and the photoelectric conversion efficiency is also better; it may be seen that the processing method of the electron transport layer provided in the present disclosure may improve the electron transport performance of the electron transport layer of the perovskite solar cell, and further may improve the battery performance and the photoelectric performance of the perovskite solar cell based on the electron transport layer.

In summary, the thin film processing method provided in the present disclosure may improve the electrical performance of the electron transport layer, thereby improving the electrical performance and service life of the light-emitting diode based on the electron transport layer and the perovskite battery thereof. The above embodiments of the present disclosure provide a thin film processing method, a preparation method of a light-emitting diode, and a light-emitting diode provided, and describe them in detail. Specific examples are used to describe the principles and implementations of the present disclosure. The description of the above embodiments is merely intended to help understand the technical solutions and the core idea of the present disclosure. It is to be understood by those of ordinary skill in the art that modifications may still be made to the technical solutions described in the foregoing embodiments, or equivalent substitutions may be made to some of the technical features therein. These modifications or substitutions do not depart the essence of the corresponding technical solutions from the scope of embodiments of the present disclosure.

1. A method of processing a thin film, comprising:
providing an electron transport layer using a metal oxide as an electron transport material; and
performing an annealing treatment to the electron transport layer by means of pulsed light in a protective gas environment having an oxygen content of 25-40 ppm;
wherein, a frequency of the pulsed light ranges from 1.5 Hz to 4 Hz, and an energy of the pulsed light ranges from 1.20 J/cm² to 2.0 J/cm².

2. The method according to claim 1, wherein a time of the annealing treatment ranges from 2 min to 5 min.

3. The method according to claim 1, wherein a wavelength of the pulsed light adopted in the annealing treatment ranges from 400 nm to 1200 nm.

4. The method according to claim 1, wherein before performing the annealing treatment to the electron transport layer by means of the pulsed light, the method further comprises: performing a passivation treatment by hydroxylation on the electron transport layer.

5. The method according to claim 4, wherein the passivation treatment by hydroxylation comprises:
placing the electron transport layer in an environment with a humidity of 1 ppm to 10 ppm for 5 min to 20 min.

6. The method according to claim 5, wherein the humidity is provided by one or more of distilled water, deionized water, highly pure water, and ultrapure water.

7. The method according to claim 5, wherein a gas in the environment comprises air or a protective gas.

8. The method according to claim 1, wherein a water vapor concentration in the protective gas environment is less than 0.1 ppm.

9. The method according to claim 1, wherein the metal oxide is selected from one or more of ZnO, TiO₂, SnO₂, Ta₂O₃, ZrO₂, NiO, TiLiO, ZnAlO, ZnSnO, ZnLiO, and InSnO.

10. The method according to claim 1, wherein after providing the electron transport layer using the metal oxide as the electron transport material, and before performing the annealing treatment to the electron transport layer by means of the pulsed light, the method further comprises: annealing the electron transport layer at 80° C.˜120° C. for 20 min˜60 min.

11. A method for preparing a light-emitting diode, comprising:
providing a substrate; and
stacking a first electrode, a hole transport layer, a light-emitting layer, an electron transport layer and a second electrode on the substrate;
wherein after the electron transport layer is formed, further comprising: processing the electron transport layer;
the processing comprises:
performing an annealing treatment to the electron transport layer by means of pulsed light in a protective gas environment having an oxygen content of 25-40 ppm.

12. The method according to claim 11, wherein a frequency of the pulsed light ranges from 1.5 Hz to 4 Hz, and an energy of the pulsed light ranges from 1.20 J/cm² to 2.0 J/cm².

13. The method according to claim 11, wherein a wavelength of the pulsed light adopted in the annealing treatment ranges from 400 nm to 1200 nm.

14. The method according to claim 11, wherein a time of the annealing treatment ranges from 2 min to 5 min.

15. The method according to claim 11, wherein a water vapor concentration in the protective gas environment is less than 0.1 ppm.

16. The method according to claim 11, wherein, after forming the hole transport layer and before the processing, the method further comprises: placing the electron transport layer in an environment with a humidity of 1 ppm to 10 ppm for 5 min to 20 min;
wherein the humidity is provided by one or more of distilled water, deionized water, high purity water, and ultrapure water.

17. The method according to claim 11, wherein the first electrode, the hole transport layer, the light-emitting layer, the electron transport layer, and the second electrode are sequentially stacked; the processing is performed before the second electrode is formed.

18. The method according to claim 11, wherein the first electrode, the electron transport layer, the light-emitting layer, the hole transport layer, and the second electrode are sequentially stacked, and the processing is performed before the light-emitting layer is formed.

19. The method according to claim 11, wherein the substrate is selected from a rigid substrate or a flexible substrate, and the material of the rigid substrate is selected from one or more of glass and metal foil; the material of the flexible substrate is selected from one or more of polyethylene terephthalate, polyether ether ketone, polystyrene, polyether sulfone, polycarbonate, polyaryl acid ester, polyarylate, polyimide, polyvinyl chloride, polyethylene, polyvinylpyrrolidone, and textile fiber;
the material of the first electrode is selected from a cathode material or an anode material, the cathode material is selected from one or more of Al, Ag, Au, Cu, Mo and their alloys, and the anode material is selected from one or more of ITO, FTO, and ZTO;
the material of the second electrode is selected from the cathode material or the anode material, the cathode material is selected from one or more of Al, Ag, Au, Cu, Mo and their alloys, and the anode material is selected from one or more of ITO, FTO, and ZTO;
the material of the hole transport layer is selected from one of an organic material having a hole transport capability and an inorganic material having a hole transport function, the organic material having the hole transport capability is selected from one or more of poly (9, 9-dioctylfluorene-CO—N-(4-butylphenyl) diphenylamine), poly(N-vinylcarbazole), poly[N,N′-bis(4-butylphenyl)-N,N′-bisphenylbenzidine], poly[(9,9-dioctylfluorenyl-2,7-diyl)-co-(N,N′-diphenyl)-N,N′di(p-butyl-oxy-phenyl)-1,4-diaMinobenzene), 4,4′,4″-Tris(carbazol-9-yl)-triphenylamine, 4,4′-Di(9H-carbazol-9-yl)-1,1′-biphenyl, N,N′-bis(3-methylphenyl)-N,N′-diphenyl-benzidine, 15N,N′-Bis(1-naphthalenyl)-N,N′-bisphenyl-(1,1′-biphenyl)-4,4′-diamine, graphene, and C60; and the inorganic material having the hole transport function is selected from one or more of NiOₓ, MoOₓ, WOₓ, CrOₓ, CuO, MoSₓ, MoSeₓ, WSₓ, WSeₓ, and CuS, wherein x is a positive number;
the material of the hole injection layer is selected from one or more of PEDOT:PSS, CuPc, F4-TCNQ, HATCN, a transition metal oxide, and a transition metal chalcogenide compound, the transition metal oxide is selected from one or more of NiOₓ, MoOₓ, WOₓ, CrOₓ, and CuO, and the transition metal chalcogenide compound is selected from one or more of MoSₓ, MoSeₓ, WSₓ, WSeₓ, and CuS, wherein x is the positive number; and
the material of the light-emitting layer is selected from one of a direct band gap compound semiconductor having light-emitting ability and a perovskite type semiconductor, the direct band gap compound semiconductor having light-emitting ability comprises one or more of a group II-VI compound, a group III-V compound, a group II-V compound, a group III-VI compound, a group IV-VI compound, a group I-III-VI compound, a group II-IV-VI compound and a group IV elemental substance, the group II-VI compound is selected from one or more of CdS, CdSe, CdTe, ZnS, ZnSe, ZnTe, HgS, HgSe, HgTe, PbS, PbSe, PbTe and other binary, ternary, quaternary II-VI semiconductor nanocrystals; the group III-V compound is selected from one or more of GaP, GaAs, InP, InAs, and other binary, ternary, quaternary III-V semiconductor nanocrystals; the perovskite type semiconductor is selected from one or more of a doped or non-doped inorganic perovskite type semiconductor, and an organic-inorganic hybrid perovskite type semiconductor, wherein a general structural formula of the inorganic perovskite type semiconductor is AMX₃, and a general structural formula of the organic-inorganic hybrid perovskite type semiconductor is BMX₃, wherein A is Cs⁺, B is an organic amine cation, M is a divalent metal cation, X is a halogen anion, the divalent metal cation comprises one of Pb²⁺, Sn²⁺, Cu²⁺, Ni²⁺, Cd²⁺, Cr²⁺, Mn²⁺, Co²⁺, Fe²⁺, Ge²⁺, Yb²⁺, and Eu²⁺; the halogen anion comprises one of Cl⁻, Br⁻, and I⁻; the organic amine cation comprises one of CH₃(CH₂)ₙ₋₂NH₃⁺ (n≥2) and NH₃(CH₂)ₙNH₃²⁺ (n≥2).

20. A light-emitting device, wherein the light-emitting device is prepared by a method for preparing a light-emitting diode, the method comprises:
providing a substrate; and
stacking a first electrode, a hole transport layer, a light-emitting layer, an electron transport layer and a second electrode on the substrate;
wherein after the electron transport layer is formed, further comprising: processing the electron transport layer;
the processing comprises:
performing an annealing treatment to the electron transport layer by means of pulsed light in a protective gas environment having an oxygen content of 25-40 ppm.
